(19) United States
(12) Patent Application Publication
(10) Pub. No.: US 2019/0101819 A1
(43) Pub. Date: Apr. 4, 2019

(54) MASK PLATE

(71) Applicants: BOE TECHNOLOGY GROUP CO., LTD., Beijing (CN); ORDOS YUANSHENG OPTOELECTRONICS CO., LTD., Inner Mongolia (CN)

(72) Inventor: Dawei SHI, Beijing (CN)

(73) Assignees: BOE TECHNOLOGY GROUP CO., LTD., Beijing (CN); ORDOS YUANSHENG OPTOELECTRONICS CO., LTD., Inner Mongolia (CN)

(21) Appl. No.: 15/550,547

(22) PCT Filed: Mar. 23, 2017
(86) PCT No.: PCT/CN2017/077812

§ 371 Date: Aug. 11, 2017

(30) Foreign Application Priority Data
May 30, 2016 (CN) 201620514549.7

(51) Int. Cl. G03F 1/38; G02F 1/1343; G02F 1/1337

(52) U.S. Cl. CPC G03F 1/38; G02F 2001/133776; G02F 1/133788; G02F 1/13439

(57) ABSTRACT

The present disclosure provides a mask plate, including a completely transparent region and a completely nontransparent region, wherein a semi-transparent structure is provided at a boundary between the completely transparent region and the completely nontransparent region, and has a light transmittance that decreases gradually from a side near the completely transparent region to a side near the completely nontransparent region.

### CROSS-REFERENCE TO RELATED APPLICATION

The present application claims priority to Chinese patent application No. 201620514549.7 titled “Mask Plate” filed on May 30, 2016, the disclosure of which is incorporated herein in its entirety by reference.

### TECHNICAL FIELD

The present disclosure relates to the field of display technology, and more particularly to a mask plate.

### BACKGROUND

During a manufacturing process of a display panel, an organic resin material will be used to form a resin layer. At some regions of the resin layer, such as a location of a FPC IC (a drive circuit on a flexible printed circuit board), the resin layer needs to be hollowed-out, which will result in exposing of a metal line below the resin layer. The resin layer needs to be provided with an electrode layer of indium tin oxide (ITO), even having a metal line thereon to improve a resistance of the ITO or to be used as lead wires. Residual metal remained at a boundary between a hollowed-out region of the resin layer will lead to a short circuit of circuit traces below the resin layer, so that the display panel cannot display normally.

At present, in order to solve the above problem, usually an ashing time of photoresists of the metal layer is increased to implement a process correcting measurement. However, since the resin is relatively thick and the boundary of the hollowed-out region of the resin layer has a relatively steep slope, the effect of the process correcting measurement is poor, which has a significant adverse affect on a critical dimension (CD).

### SUMMARY

An object of the present disclosure is to provide a mask plate. By improving the mask plate, for example, a slope profile of a boundary of a hollowed-out region of a resin layer formed by using the mask plate can be improved, thus avoiding an occurrence of a short circuit between upper-layer metal and lower-layer metal of the resin layer.

The technical solution provided by the present disclosure is as follows.

A mask plate including a completely transparent region and a completely nontransparent region, wherein a semi-transparent structure is provided at a boundary between the completely transparent region and the completely nontransparent region, and has a light transmittance that decreases gradually from a side near the completely transparent region to a side near the completely nontransparent region.

Optionally, the semi-transparent structure comprises a plurality of light shielding blocks at the boundary of the completely transparent region and the completely nontransparent region, and the plurality of light shielding blocks is arranged at intervals along a boundary line between the completely transparent region and the completely nontransparent region.

Further, a gap between two adjacent light shielding blocks is of a pre-determined value so as to enable a light diffraction to occur between the two adjacent light shielding blocks, and/or a pre-determined gap between two adjacent light shielding blocks has a width that is less than a resolution of an exposure machine adopted in a mask process.

Further, each gap between any two adjacent light shielding blocks of the plurality of light shielding blocks has an identical width.

Further, each of the plurality of light shielding blocks is a rectangular block which is completely nontransparent.

Further, light transmittances of gaps between any two adjacent light shielding blocks of the plurality of light shielding blocks decrease gradually from a side near the completely transparent region to a side near the completely nontransparent region.

Further, each of the plurality of light shielding blocks and the completely nontransparent region of the mask plate are made of an identical material, and are integrally connected with each other.

Optionally, the mask plate is configured for a mask process at a resin layer, the resin layer comprises a hollowed-out region corresponding to the completely transparent region and a non-hollowed-out region corresponding to the completely nontransparent region, and a metal layer is formed in a first boundary region of the non-hollowed-out region at a boundary between the non-hollowed-out region and the hollowed-out region of the resin layer; and the boundary between the completely transparent region and the completely nontransparent region of the mask plate is provided with a plurality of boundary lines, and the plurality of boundary lines comprises at least a first boundary line corresponding to the first boundary region, and the semi-transparent structure is arranged at a location corresponding to the first boundary line.

Optionally, the completely transparent region comprises at least two completely transparent sub-regions, and the semi-transparent structure is provided at a boundary between each of the at least two completely transparent sub-regions and the completely nontransparent region.

Optionally, the two completely transparent sub-regions comprise a first completely transparent sub-region and a second completely transparent sub-region, an area of the first completely transparent sub-region is different from that of the second completely transparent sub-region, a plurality of first light shielding blocks is provided at a boundary between the first completely transparent sub-region and the completely nontransparent region, and a plurality of second light shielding blocks is provided at a boundary between the second completely transparent sub-region and the completely nontransparent region.

Further, the area of the first completely transparent sub-region is greater than that of the second completely transparent sub-region.

Further, a size of the first light shielding block is equal to or greater than that of the second light shielding block.

The beneficial effects of the present disclosure are as follows.

According to the mask plate provided by the present disclosure, the boundary between the completely transparent region and the completely nontransparent region is provided with the semi-transparent structure having the light transmittance that decreases gradually from the side near the completely transparent region to the side near the completely nontransparent region, so as to control and improve the gradient of the slope of the boundary of the hollowed-out region formed on the resin layer by using the mask plate. The gradient of the slope becomes gentler, thus avoiding the occurrence of the short circuit between upper-layer metal and lower-layer metal of the resin layer due to the steep slope of the boundary of the hollowed-out region of the resin layer.

### BRIEF DESCRIPTION OF THE DRAWINGS

FIG. 1 is a schematic view showing an occurrence of a short circuit at a hollowed-out region of a resin layer in a related art;

FIG. 2 is schematic view showing a cross-section structure of a slope of a boundary of the hollowed-out region of the resin layer in the related art;

FIG. 3 is schematic view showing a structure of a mask plate provided by the present disclosure in some embodiments;

FIG. 4 is a schematic view showing a structure of a mask plate provided by the present disclosure in some embodiments;

FIG. 5 is a schematic view showing a cross-section structure of a slope formed at a boundary of a hollowed-out region of the resin layer of the mask plate provided by the present disclosure in some embodiments.

### DETAILED DESCRIPTION

In order to make the objects, the technical solutions and the advantages of the present disclosure more apparent, the present disclosure will be described hereinafter in a clear and complete manner in conjunction with the drawings and embodiments. Obviously, the following embodiments are merely a part of, rather than all of, the embodiments of the present disclosure, and based on these embodiments, a person skilled in the art may obtain the other embodiments, which also fall within the scope of the present disclosure.

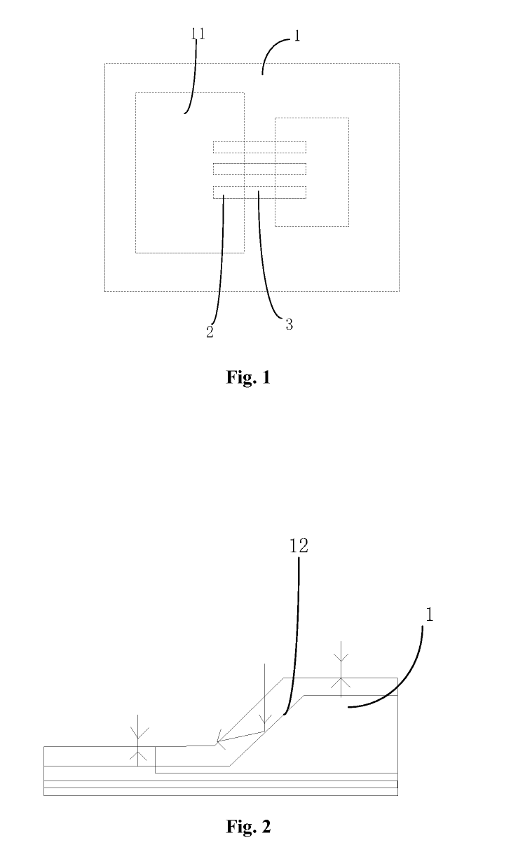

In a related art, exemplarily, as shown in FIG. 1 and FIG. 2, a slope 12 of a boundary of a hollowed-out region 11 of a resin layer 1 of a display panel is relatively steep, and metal traces 2 below the resin layer 1 will be exposed after the resin layer 1 being hollowed-out, and then a metal layer 3 is deposited. During a photoetching process, since a gradient of the slope 12 of the boundary of the hollowed-out region 11 of the resin layer 1 is large, a coating thickness of a photoresist at the slope 12 of the boundary is large. After exposure, light beams irradiated on a tilted surface of the slope 12, reflected light beams are scattered and irregular, which affect exposure efficient and absorption of ultraviolet light by the photoresist. As a result, residual photoresist still remains at the slope of the boundary of the hollowed-out region 11 of the resin layer 1 after a development process. During a subsequent etching process, the metal layer 3 may not be etched thoroughly because of the influence of the photoresists, so that the metal exists at the slope of the resin layer 1, which causes an occurrence of a short circuit between metal traces 2 below the resin layer, resulting in an abnormal display and a functional failure.

In a related art, a transparent region and a nontransparent region on the mask plate are a region that has a light transmittance of 100% and a region that has light transmittance of 0, respectively. A contrast ratio between the transparent region and the nontransparent region is high, and a thickness of the resin layer is large, which causes a large slope at the boundary of the hollowed-out region of the resin layer after the resin layer being exposed and developed. Since the slope of the boundary is steep, the photoresist may hardly be exposed and developed sufficiently during the subsequent coating process.

Regarding an abnormal display that caused by the occurrence of the short circuit between the upper-layer metal trace and the lower-layer metal trace due to the steep slope of the boundary of the hollowed-out region of the resin layer, in the present disclosure, the key of solving the above problem is shifted to an improvement of a structure of the mask plate from a processing adjustment, so as to improve the slope of the boundary of the hollowed-out region of the resin layer.

The mask plate provided by the present disclosure is capable of improving such as the slope profile of boundary of the hollowed-out region of the resin layer formed using the mask plate, by improving the mask plate, thus avoiding the occurrence of the short circuit between the upper-layer metal and the lower-layer metal of the resin layer.

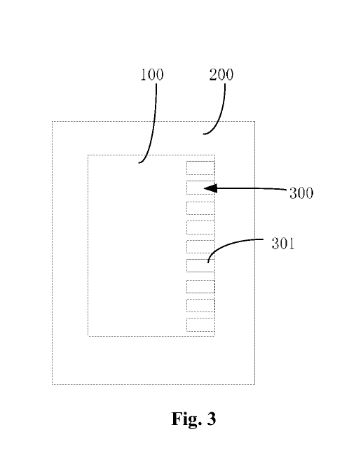

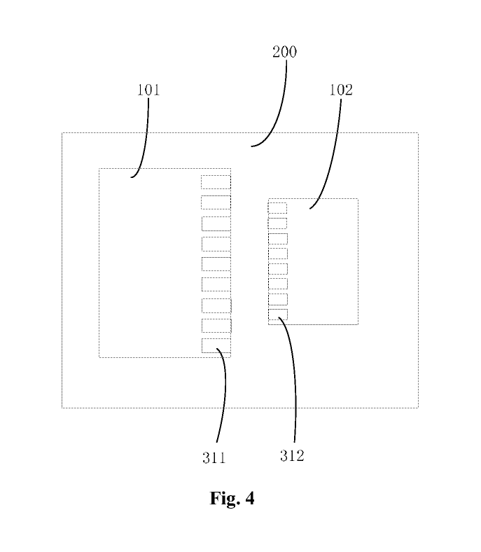

As shown in FIG. 3, the mask plate provided by the present disclosure includes a completely transparent region 100 and a completely nontransparent region 200. A semi-transparent structure 300 (may also be called a partially transparent structure) is provided at a boundary between the completely transparent region 100 and the completely nontransparent region 200 is provided with, and a light transmittance of the semi-transparent structure 300 is between that of the completely transparent region 100 and that of the completely nontransparent region 200. Optionally, the light transmittance of the semi-transparent structure 300 decreases gradually from a side near the completely transparent region 100 to a side near the completely nontransparent region 200.

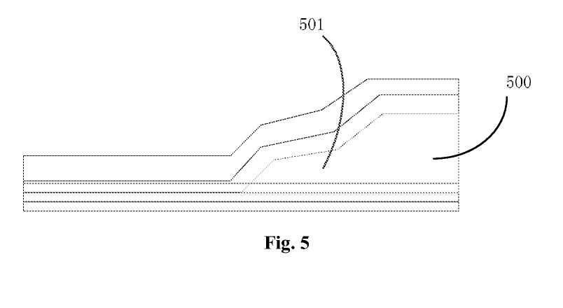

According to the mask plate provided by the present disclosure, the boundary of the completely transparent region 100 and the completely nontransparent region 200 is provided with the semi-transparent structure 300, and the light transmittance of the semi-transparent structure 300 decreases gradually form the side near the completely transparent region 100 to the side near the completely nontransparent region 200. As shown in FIG. 5, a gradient of the slope 501 of the boundary of the hollowed-out region formed on the resin layer 500 by the mask plate may be controlled and improved. Compared with the related art, the gradient of the slope 501 becomes moderate. During the subsequent photoetching process of the metal layer above the resin layer 500, since the gradient of the slope 501 of the boundary of the hollowed-out region of the resin layer 500 is moderate, the difference among thicknesses of photoresists is minor. In addition, because of better exposure efficiency and reflectivity, and the residual photoresists is reduced, thus avoiding the occurrence of the short circuit between the upper-layer metal and the lower-layer metal of the resin layer 500 due to the steep slope 501 of the boundary of the hollowed-out region of the resin layer 500.

In the mask plate provided by the present disclosure, as shown in FIG. 3, optionally, the semi-transparent structure 300 includes a plurality of light shielding blocks 301 (the number of the light shielding blocks may be two or more) at the boundary of the completely transparent region 100 and the completely nontransparent region. 200, arranged at intervals along a boundary line between the completely transparent region 100 and the completely nontransparent region 200.

By adopting the above solution, the semi-transparent structure 300 may be formed by arranging the plurality of light shielding blocks 301 having a pre-determined length successively at the boundary between the completely transparent region 100 and the completely nontransparent region 200. As shown in FIG. 3, there are gaps between any two adjacent light shielding blocks of the plurality of light shielding blocks 301, and the gas have light transmittances greater than 0 and less than 100%. Optionally, the light transmittances of the gaps decreases gradually from the side near the completely transparent region 100 to the side near the completely nontransparent region 200, which makes the slope 501 of the boundary of the hollowed-out region gentle when forming the hollowed-out region on the resin layer 500 using the mask plate.

It should be understood that, the above solution merely provides an optional embodiment of the semi-transparent structure 300. In other embodiments of the present disclosure, the semi-transparent structure 300 may also be implemented in a different manner. For example, the semi-transparent structure 300 may be a one-piece light shielding plate having a light transmittance decreases gradually from the side near the completely transparent region 100 to the side near the completely nontransparent region 200.

In addition, in an embodiment provided by the present disclosure, optionally, a gap between two adjacent light shielding blocks 301 is of a pre-determined value so as to enable a light diffraction to occur between the two adjacent light shielding blocks 301. Optionally, the pre-determined gap has a width that is less than a resolution of an exposure machine used in a mask process.

In the above solution, the gap between two adjacent light shielding blocks 301 is less than the resolution of the exposure machine. Owing to a diffraction effect, the light shielding block 301 has a certain light transmittance therebelow, and the photoresists will not be developed completely, thus substantially forming three sections of slope (i.e., a complete developing section, a partial developing section and a complete non-developing section) at the boundary of the hollowed-out region of the resin layer 500. Moreover, the light transmittances of the gaps between light shielding blocks 301 gradually decreases from the side near the completely transparent region 100 to the side near the completely nontransparent region 200, so that the slope 501 for connection is gentle.

In addition, in an embodiment provided by the present disclosure, optionally, as shown in FIG. 3, each gap between any two adjacent light shielding blocks 301 has an identical width along a direction from the side near the completely transparent region 100 to the side near the completely nontransparent region. By adopting the above solution, it may be ensured that the gradients at all locations of the slope 501 formed at the boundary of the hollowed-out region of the resin layer 500 are identical.

In addition, in an embodiment provided by the present disclosure, optionally, the light shielding block 301 may be a rectangular block which is completely nontransparent. Optionally, the light shielding block 301 and the completely nontransparent region 200 of the mask plate are made of a same material, and integrally connected with each other. By adopting the above solution, the manufacturing process of the mask plate is simple.

It should be understood that, in other embodiments of the present disclosure, other structures may also be adopted in the light shielding block 301, which shall not be limited herein.

In addition, it should be noted that, the hollowed-out region on the resin layer 500 on the display substrate usually is defined by the completely transparent region 100 on the mask plate, and the non-hollowed-out region on the resin layer 500 usually is defined by the completely nontransparent region 200 on the mask plate, and a metal layer is formed in a first boundary region of the non-hollowed-out region at a boundary between the non-hollowed-out region and the hollowed-out region of the resin layer 500.

In an embodiment provided by the present disclosure, optionally, the boundary between the completely transparent region 100 and the completely nontransparent region 200 of the mask plate is provided with a plurality of boundary lines, and the plurality of boundary lines includes at least a first boundary line corresponding to the first boundary, and the semi-transparent structure 300 is only arranged at a location corresponding to the first boundary line.

That is, the mask plate provided by the embodiment may provide the semi-transparent structure 300 only arranged at a location corresponding to a side of the resin layer 500 where the metal traces need to be formed subsequently, while other boundary lines at the boundary between the completely transparent regions 100 and the completely nontransparent region 200 may not be provided with the semi-transparent structure 300.

In addition, in an embodiment provided by the present disclosure, optionally, the completely transparent region 100 includes at least two completely transparent sub-regions, and each boundary of the completely transparent sub-region and the completely nontransparent region 200 is provided with the semi-transparent structure 300.

Optionally, as shown in FIG. 4, taking the two completely transparent sub-regions as an example, the two completely transparent sub-regions 100 are a first completely transparent sub-region 101 and a second completely transparent sub-region 102 respectively, an area of the first completely transparent sub-region 101 is different from that of the second completely transparent sub-region 102, a boundary between the first completely transparent sub-region 101 and the completely nontransparent region 200 is provided with a plurality of first light shielding blocks 311, and a boundary between the second completely transparent sub-region 102 and the completely nontransparent region 200 is provided with a plurality of second light shielding blocks 312.

By adopting the above solution, each light shielding block 301 may be adaptively adjusted. The light shielding blocks 301 arranged at the completely transparent sub-regions 100 with different areas may have the same size or may have different sizes. Optionally, the area of the first completely transparent sub-region 101 is greater than that of the second completely transparent sub-region 102, and a size of the first light shielding block 311 is equal to or greater than that of the second light shielding block 312.

The above are merely the optional embodiments of the present disclosure. It should be noted that, a person skilled in the art may make improvements and modifications without departing from the principle of the present disclosure, and these improvements and modifications shall also fall within the scope of the present disclosure.

1. A mask plate comprising a completely transparent region and a completely nontransparent region;
wherein a semi-transparent structure is provided at a boundary between the completely transparent region and the completely nontransparent region, and has a light transmittance that decreases gradually from a side near the completely transparent region to a side near the completely nontransparent region.

2. The mask plate according to claim 1, wherein
the semi-transparent structure comprises a plurality of light shielding blocks at the boundary of the completely transparent region and the completely nontransparent region, and the plurality of light shielding blocks is arranged at intervals along a boundary line between the completely transparent region and the completely nontransparent region.

3. The mask plate according to claim 2, wherein
a gap between two adjacent light shielding blocks is of a pre-determined value so as to enable a light diffraction to occur between the two adjacent light shielding blocks.

4. The mask plate according to claim 2,
wherein a pre-determined gap between two adjacent light shielding blocks has a width that is less than a resolution of an exposure machine adopted in a mask process.

5. The mask plate according to claim 2, wherein
each gap between any two adjacent light shielding blocks of the plurality of light shielding blocks has an identical width.

6. The mask plate according to claim 2, wherein
each of the plurality of light shielding blocks is a rectangular block which is completely nontransparent.

7. The mask plate according to claim 2, wherein
light transmittances of gaps between any two adjacent light shielding blocks of the plurality of light shielding blocks decrease gradually from a side near the completely transparent region to a side near the completely nontransparent region.

8. The mask plate according to claim 2, wherein
each of the plurality of light shielding blocks and the completely nontransparent region of the mask plate are made of an identical material, and are integrally connected with each other.

9. The mask plate according to claim 1, wherein
the mask plate is configured for a mask process at a resin layer, the resin layer comprises a hollowed-out region corresponding to the completely transparent region and a non-hollowed-out region corresponding to the completely nontransparent region, and a metal layer is formed in a first boundary region of the non-hollowed-out region at a boundary between the non-hollowed-out region and the hollowed-out region of the resin layer; and
the boundary between the completely transparent region and the completely nontransparent region of the mask plate is provided with a plurality of boundary lines, and the plurality of boundary lines comprises at least a first boundary line corresponding to the first boundary region, and the semi-transparent structure is arranged at a location corresponding to the first boundary line.

10. The mask plate according to claim 1, wherein
the completely transparent region comprises at least two completely transparent sub-regions, and the semi-transparent structure is provided at a boundary between each of the at least two completely transparent sub-regions and the completely nontransparent region.

11. The mask plate according to claim 10, wherein
the two completely transparent sub-regions comprise a first completely transparent sub-region and a second completely transparent sub-region, an area of the first completely transparent sub-region is different from that of the second completely transparent sub-region, a plurality of first light shielding blocks is provided at a boundary between the first completely transparent sub-region and the completely nontransparent region, and a plurality of second light shielding blocks is provided at a boundary between the second completely transparent sub-region and the completely nontransparent region.

12. The mask plate according to claim 11, wherein
the area of the first completely transparent sub-region is greater than that of the second completely transparent sub-region.

13. The mask plate according to claim 11, wherein
a size of the first light shielding block is equal to or greater than that of the second light shielding block.
